(19) United States
(12) Patent Application Publication
(10) Pub. No.: US 2014/0060646 A1
(43) Pub. Date: Mar. 6, 2014

(54) HIGH OPTICAL QUALITY POLYCRYSTALLINE INDIUM PHOSPHIDE GROWN ON METAL SUBSTRATES BY MOCVD

(71) Applicants: Maxwell Zheng, Berkeley, CA (US); Ali Javey, Lafayette, CA (US)

(72) Inventors: Maxwell Zheng, Berkeley, CA (US); Ali Javey, Lafayette, CA (US)

(73) Assignee: The Regents of the University of California, Oakland, CA (US)

(21) Appl. No.: 14/011,443

(22) Filed: Aug. 27, 2013

Related U.S. Application Data
(60) Provisional application No. 61/694,653, filed on Aug. 29, 2012.

(51) Int. Cl. H01L 31/0304; H01L 31/0216; H01L 31/18; H01L 31/0368

(52) U.S. Cl. CPC H01L 31/0304; H01L 31/0368; H01L 31/02167; H01L 31/184
USPC 136/258; 438/93

(57) ABSTRACT

A new solar cell is disclosed wherein the solar cell comprises a substrate, a VIB metal thin film deposited on the substrate, and a polycrystalline III-V semiconductor thin film deposited on the VIB metal thin film.

A method of making the solar cell is described comprising providing a substrate, depositing a VIB metal thin film on the substrate, and depositing a polycrystalline III-V semiconductor thin film on the VIB metal thin film. In one embodiment a polycrystalline III-V semiconductor thin film comprising Indium Phosphide (InP) is deposited on a VIB metal thin film comprising Molybdenum (Mo) by Metal Organic Chemical Vapor Deposition (MOCVD).

### CROSS REFERENCE TO RELATED APPLICATIONS

This U.S. Application claims priority to U.S. Provisional Application Ser. No. 61/694,653 filed Aug. 29, 2012, which application is incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-ACO2-05CH11231 between the U.S. Department of Energy and the Regents of the University of California for the management and operation of the Lawrence Berkeley National Laboratory. The government has certain rights in this invention.

### BACKGROUND OF THE INVENTION

1. Field of the Invention

This invention relates generally to solar cells, and, more specifically to polycrystalline (poly) III-V semiconductor solar cells and methods for making the same.

2. Brief Description of the Related Art

III-V semiconductor solar cells have demonstrated the highest power conversion efficiencies to date.^{[1]} Specifically, Indium Phosphide (InP) and Gallium Arsenide (GaAs) have the most ideal band gaps and highest theoretical efficiencies for single-junction cells. However, the cost of III-V solar cells has historically been too high to be practical outside of specialty applications. This stems from the cost of raw materials, need for a lattice-matched substrate for epitaxial growth of single crystals, and complex epitaxial growth processes.^{[2],[3]} To address these issues, layer transfer techniques have been explored in the past where thin epitaxial films of GaAs and InP are selectively peeled and transferred from the growth substrate to a user-defined receiver substrate.^{[3]-[8]} The layer transfer techniques enable the growth substrate to be used multiple times, thereby potentially lowering the manufacturing cost. However, these techniques also add additional complexity and decreased reliability. What is needed in the solar industry is the development of low-cost and yet efficient polycrystalline (poly) III-V solar cells.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 illustrates (a) a poly-InP fabrication scheme, (b) poly-InP on flexible molybdenum foil, (c) poly-InP on sputtered Mo on a 3″ wafer.

FIG. 2 illustrates (a) a SEM top view of poly-InP grown at 520° C. for 75 minutes, (b) a cross-sectional SEM image of poly-InP grown on a Mo thin film at 520° C. for 75 minutes. The InP is on top of ˜50 nm MoₓP₁₋ₓ/50 nm SiO₂/Si. c) TEM image at a grain boundary. Inset shows FFT from within the left grain. (d) TEM of interface between InP and Mo/MoₓP₁₋ₓ.

FIG. 3 illustrates a growth temperature series showing increasing grain size with growth temperature.

FIG. 4 illustrates (a) a side view SEM image of sample grown on a Mo thin film at 500° C. for 75 minutes, (b) a TEM image of same sample showing stacking faults.

FIG. 5 illustrates a TEM image of the ˜8.5 nm transition layer of MoₓP₁₋ₓ between InP (top) and Mo foil (bottom).

FIG. 6 illustrates XRD spectra as a function of growth temperature.

FIG. 7 illustrates Raman spectra measured at room temperature.

FIG. 8 illustrates room temperature photo luminescence (PL) change with growth temperature.

### DETAILED DESCRIPTION

In the discussions that follow, various process steps are described using certain types of manufacturing equipment, along with certain process parameters. It is to be appreciated that other types of equipment can be used, with different pressure and gas concentrations employed, and that some of the steps may be performed in the same chamber without departing from the scope of this invention. Furthermore, different component gases could be substituted for those described herein without departing from the scope of the invention. These and other details and advantages of the present invention will become more fully apparent from the following description taken in conjunction with the accompanying drawings.

In the present invention, a new approach is disclosed for the fabrication of polycrystalline (poly) III-V semiconductor solar cells. Embodiments of the invention describe a method of directly growing thin (˜1-3 μm) polycrystalline (poly) layers of III-V semiconductor on metal substrates, both thin films and foils. This approach minimizes the amount of raw semiconductor material used and swaps a high-cost lattice matched substrate for a low-cost one. In addition, metal foils lend themselves to low-cost roll-to-roll processing schemes, act as excellent diffusion barriers to the environment, and exhibit high thermal stability.

Thin film growth on non-epitaxial substrates invariably results in polycrystalline (poly) materials which presents certain constraints and challenges. In particular, the increased surface/interface area and grain boundaries may act as efficient recombination centers for photogenerated minority carriers. Thus, the use of materials with a low surface recombination velocity (SRV) is required to ensure high efficiency poly III-V solar cells. Untreated InP has a significantly lower SRV (˜10³ cm s⁻¹)^{[9]-[15]} as compared to GaAs (˜10⁶ cm s⁻¹)_{[15],[16]} making it an ideal candidate for efficient poly-crystalline cells. However, while poly-GaAs has been widely explored in the past,^{[17],[18]} there have been few reports of poly-InP in terms of growth techniques,^{[19]-[21]} material quality,^{[9],[22]} or device performance.^{[23],[24]}

Embodiments of the invention describe high optical quality poly-InP thin films grown on molybdenum (Mo) thin film and foil substrates, by metal organic chemical vapor deposition (MOCVD). The materials and optical characteristics of the grown films were systematically determined as a function of growth conditions. Poly-InP films grown at an optimal temperature exhibit highly promising properties with the photoluminescence spectra closely matching that of a single-crystalline InP. Crystal quality was evaluated as the absence of defects and dislocations, as well as grain size and XRD line width. Embodiments of the invention described herein enable the development of low-cost and yet efficient polycrystalline (poly) III-V solar cells.

Embodiments of the invention demonstrate that the choice of substrate metal is important for obtaining high quality poly-InP films. At a given growth temperature, the substrate metal should have low solubility of both indium and phosphorus. Ideally, the substrate metal should either not form indium alloys or metal phosphides, or if it does, the reaction should be self-limiting. In addition, the substrate metal should have a similar thermal expansion coefficient as InP.^{[24]}

From metal-P and metal-In phase diagrams, molybdenum (Mo) and tungsten (W) meet the above criteria. For Mo in particular, there are no intermetallics at for a range of growth temperatures, and the solubility of In is very low. There are few Mo—P compounds, and no solid solutions; this suggests the loss of phosphorous into the substrate may be minimal.

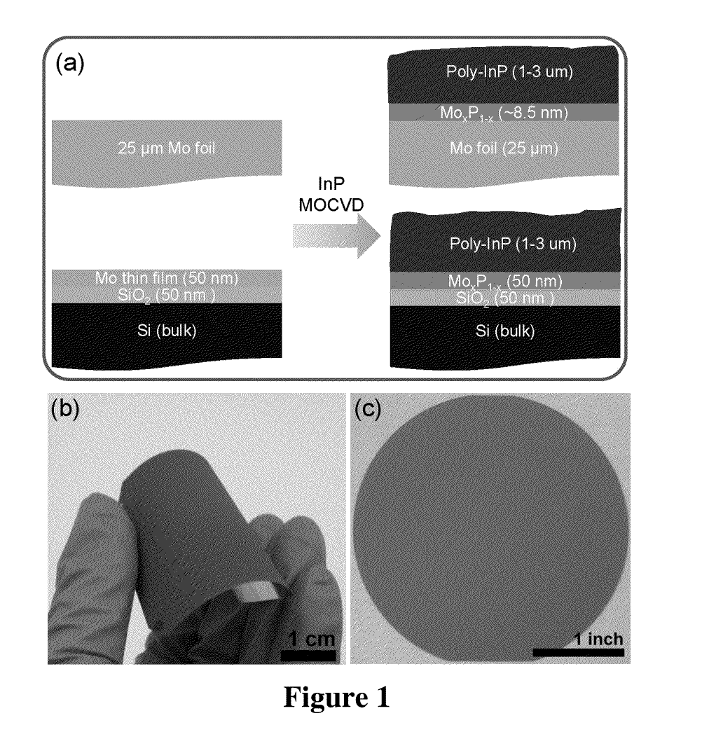

FIG. 1 illustrates (a) a poly-InP fabrication scheme, (b) poly-InP on flexible molybdenum foil, (c) poly-InP on a sputtered Mo thin film on a 3″ wafer. The lighter ring on the outer edge of the wafer is due to edge effects from the susceptor.

Embodiments of the invention describe the utilization of Mo, both in the form of thin metal foils and thin films. The Mo foils used were 25 μm thick and cleaned with acetone and isopropanol prior to growth. It will be appreciated that tungsten (W) and other VIB elements may also be utilized as a substrate.

Alternatively, Si/SiO₂ wafers, i.e., silicon (Si) wafers with a thin SiO₂ layer (thermal oxide, 50 nm thickness) and subsequently sputtered with a chromium (Cr) adhesion layer (5 nm thickness) and Mo (50 nm thickness) top film were also utilized as a growth substrate.

Subsequently, polycrystalline InP thin films were grown on top of these Mo substrates by MOCVD as schematically illustrated in FIG. 1a.

Optical images of poly InP thin films (˜2 μm thickness) grown on flexible Mo foil and sputtered Mo thin film substrates (510° C. and 75 minutes) are shown in FIGS. 1b and 1c, respectively. Embodiments of the invention describe the growth of uniform films over ˜40 cm² foils (FIGS. 1(b)) and 3″ diameter wafers (FIG. 1(c)), limited only by the sample holder size of the MOCVD equipment used. As evident from visual inspection, the grown poly InP films exhibit large area uniformity and continuity. As described below, embodiments of the invention describe the growth data on the Mo thin film substrate. In general, the growth properties were found to be similar between the two types of substrates.

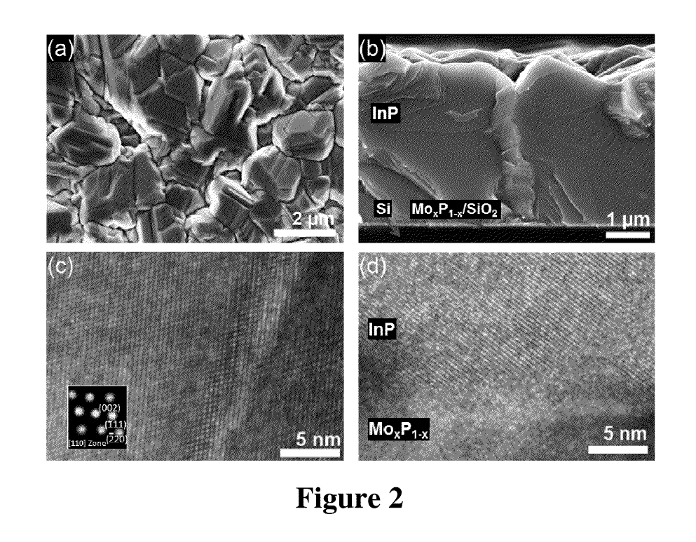

The details of the growth process are described below in the Experimental section. Certain embodiments of the invention focus on the effects of growth time and temperature. FIG. 2 illustrates (a) a SEM top view of poly-InP grown at 520° C. for 75 minutes, (b) a cross-sectional SEM image of poly-InP grown on a Mo thin film at 520° C. for 75 minutes. The InP film (˜3 μm thickness) is on top of ˜50 nm MoₓP₁₋ₓ/50 nm Si0₂/Si. The grown InP films are poly-crystalline and continuous. The grains generally extend from the surface to the substrate, but are oriented randomly. The average grain size and surface roughness of the thin film for this growth condition are ˜2 μm and ˜200 nm, respectively—both of which are highly depend on the growth temperature.

FIG. 2(c) illustrates TEM image at a grain boundary. Inset shows Fast Fourier Transform (FFT) from within the left grain. FIG. 2(d) illustrates TEM of interface between InP and Mo/MoₓP₁₋ₓ.

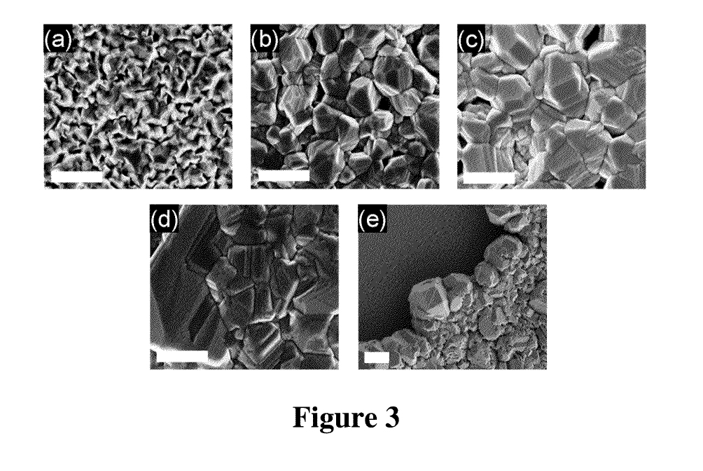

FIG. 3 illustrates a growth temperature series showing increasing grain size with growth temperature. Samples are all grown on Mo thin films. FIGS. 3(a) 445° C., (b) 480° C., (c) 500° C., (d) 520° C., and (e) 545° C. Scale bars in (a-d) are 2 μm, scale bar in (e) is 10 μm.

From SEM and TEM analyses, the grain sizes range from ˜0.5 μm for 445° C. growth temperature to ˜10 μm for 545° C. While the grain size increases with temperature, the grown InP is not continuous at ≧545° C. for a fixed growth time of 75 minutes. This observation is expected given the reduced number of nucleation sites at higher temperatures.

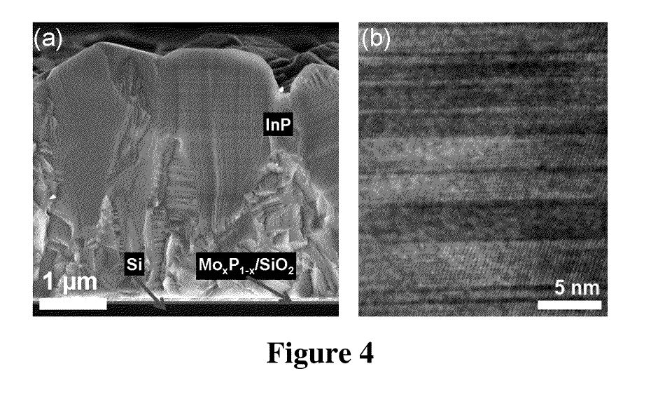

At growth temperatures of ≦500° C., striations are clearly present within each grain oriented parallel to the substrate based on SEM inspection. FIG. 4 (a) illustrates a side view SEM image of sample grown on a Mo thin film at 500° C. for 75 minutes. A grain without striations (left) is shown next to two with horizontal striations (right). FIG. 4 (b) illustrates a TEM image of same sample showing stacking faults.

From TEM analysis, the striations correspond to stacking faults. Each layer appears to consist of ˜10-100 close packed planes. Similar stacking faults and twinning have been observed in metalorganic vapor phase epitaxy grown InP nanowires in the [111] direction.^{[25],[26] The data is also consistent with the known low stacking fault energy of InP.}^{[27]} However, at growth temperatures of ≧520° C., the density of stacking faults are drastically reduced with only a minimal number of such defects being evident in TEM analysis (see FIG. 2c). The appearance of stacking faults suggests the growth mechanism after nucleation is layer-by-layer of close packed planes ([111] direction in a zincblende lattice). This is similar to the traditional growth of epitaxial layers, where the underlying substrate is cut slightly off axis to facilitate layer-by-layer growth at terraces. Altogether, crystal quality appears to be higher at higher growth temperatures. Considering both crystal quality and film continuity constraints, 520° C. is found to be the optimal growth temperature for a fixed growth time of 75 minutes.

Further, TEM study indicates the interface between InP and Mo is continuous and free of voids, as seen in FIG. 2d. Composition analysis reveals significant phosphorus content throughout the initial 50 nm Mo layer. It appears to be composed of a mixture of Mo and MoₓP₁₋ₓ phases, where x ranges from ˜0.8 to ˜0.5 from low to high growth temperatures as confirmed by EDS/TEM analysis.

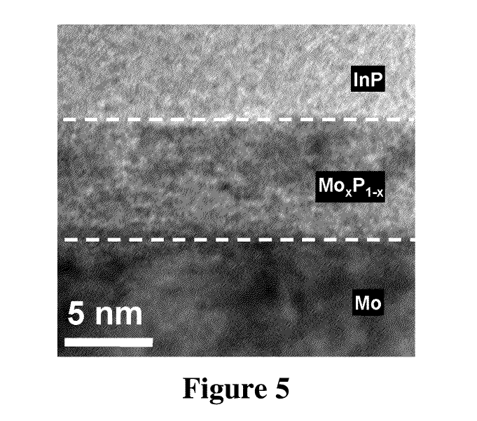

In contrast, InP on Mo foil samples showed a similar MoₓP₁₋ₓ layer, where x ranged from ˜0.6 to ˜0.4. However, this layer was self-limited to a thickness of only ˜8.5 nm. FIG. 5 illustrates a TEM image of the ˜8.5 nm transition layer of MoₓP₁₋ₓ between InP (top) and Mo foil (bottom). This is attributed to the larger grain sizes of the foil vs. the sputtered Mo, and corresponding lower reactivity. Close examination reveals that in some locations, the InP lattice matches that of the underlying MoₓP₁₋ₓ, suggesting a high quality interface. Note that in contrast to the results here, Ni foil substrates in the same growth conditions showed uncontrollable reactions with phosphorus and indium. This is consistent with presence of solid solutions at the growth temperatures in the In—Ni and Ni—P phase diagrams. The surface of the foils becomes pitted and cracked and no InP film was able to grow.

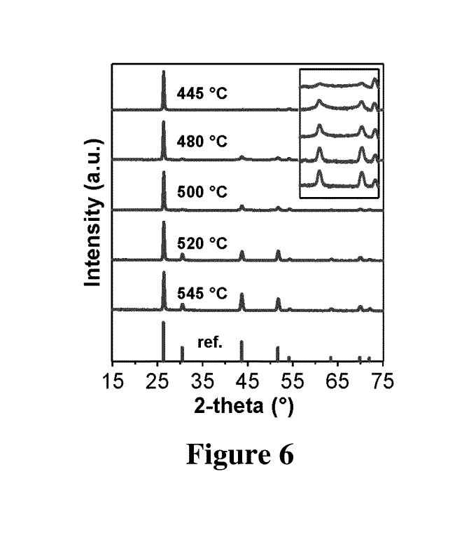

The grown InP films were characterized by XRD. FIG. 6 illustrates XRD spectra as a function of growth temperature. Curves are normalized to the (111) peak and offset. Inset, log scale, shows the gradual narrowing of the (220) and (311) peaks. Reference data are from the ICDD PDF. From left to right the first five peaks are: (111), (200), (220), (311), and (222). The XRD analysis further shows texture at lower growth temperatures, with only the (111) and (222) peaks noticeable. The peak positions match those of zincblende InP.^{[28],[29]} As the growth temperature increases, additional peaks appear, indicating the grains become more randomly oriented. At the highest growth temperature of 545° C., the relative peak intensities are a close match to the ICDD powder reference.^{[29]} In addition, the line widths of the (220) and (311) peaks get progressively narrower as growth temperature increases, indicating a greater level of crystallinity. There is no evidence of wurtzite InP peaks,^{[28]} especially the (0002) peak which would show up close to (111) zincblende peak, indicating that the stacking faults do not result in a phase change from zincblende to wurtzite.

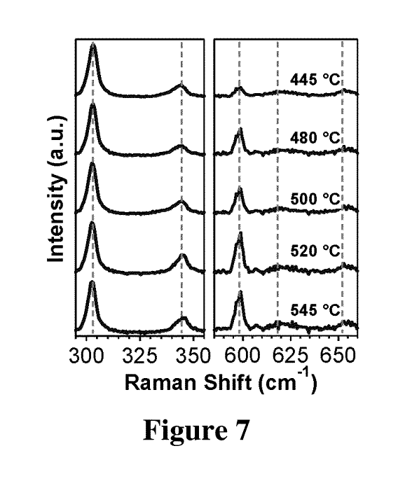

FIG. 7 illustrates Raman spectra measured at room temperature. Data is normalized to the ΓTO peak and offset. The left graph shows the first order peaks, ΓTO and ΓLO, from left to right. The right graph shows second order peaks, XLO+XTO, 2ΓTO, and ΓLO+ΓTO, from left to right. Intensity of data in right graph is 5x. Raman spectra for films grown at all temperatures (445° C.-545° C.) match well with that reported in the literature for a single-crystalline InP substrate.^{[30]-[32]} The first order anti-Stokes ΓTO and ΓLO peaks show up at ˜303 cm⁻¹ and ˜344 cm⁻¹ respectively. The data are all normalized to the ΓTO peak intensity. The relative intensity of the ΓLO peak increases slightly with growth temperature. In addition, the ΓLO peak shows a pronounced asymmetry towards lower energy. Second order features corresponding to the XLO+XTO, 2ΓTO, and ΓLO+ΓTO interactions also appeared.^{[30],[32]} Of these, only the XLO+XTO feature intensity showed a strong correlation with growth temperature. While the intensity increases with growth temperature, the shape remains unchanged. The features here are consistent with a randomly oriented poly-InP film.

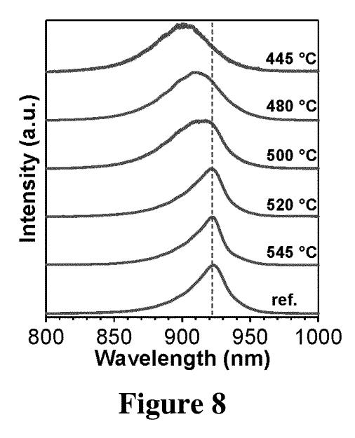

FIG. 8 illustrates room temperature photo luminescence (PL) change with growth temperature. Higher growth temperatures exhibit near identical shape and position as a single crystal reference. Curves are normalized and offset. Room temperature micro-PL data also shows a clear trend of increasing quality with growth temperature. As a metric, poly-InP PL spectra is compared to a non-degenerately doped single crystal InP reference, as well as previously reported values in the literature. At the two highest growth temperatures (520° C. and 545° C.), the peak position, full-width-at-half-maximum (FWHM), and shape are nearly identical to a single-crystal reference sample. Although the level of unintentional doping is unknown, this is evidence that the optical qualities of poly-InP are comparable to single crystal InP. At lower growth temperatures, the spectra are blue-shifted, FWHM is broad, and the shape is symmetric. The trend is summarized in Table 1.

TABLE 1
PL peak positions and FWHMs as a function of growth temperature.

| Growth | Peak Position | FWHM |
|---|---|---|
| temperature (° C.) | (nm) | (nm) |
| 445 | 898.5 | 46 |
| 480 | 908.8 | 46 |
| 500 | 917.0 | 45 |
| 520 | 921.6 | 30 |
| 545 | 922.4 | 26 |
| Ref [a] | 923.4 | 28 |

[a] Single crystal sample

Note that the 520° C. and 545° C. peaks at ˜922 nm correspond to the direct band gap energy of ˜1.34 eV,^{[33],[34]} matching closely the expected band-gap of InP, whereas the 445° C. peak at ˜898.5 nm corresponds to ˜1.38 eV. Such blue-shifts have been observed for InP nanowires with stacking faults, and have been attributed to the presence of the wurtzite phase or quantum confinement, both of which increase the band gap.^{[25],[35]} While there is clearly a correlation between stacking fault prevalence due to growth temperature and PL characteristics in our InP, the SEM and XRD data do not indicate the presence of a wurtzite phase.

Also important to note is that the PL feature from the 500° C. sample is plainly composed of two overlapping peaks, as can be seen by the asymmetry and flat top. Moreover, the relative intensities of the two contributions varied as the sample was scanned laterally (not shown). This is consistent with the SEM/TEM analyses, which shows grains with stacking faults next to those without such defects. There is also a clear transition temperature between 500° C. and 520° C. where the optical transitions corresponding to the higher energy peak are totally suppressed, leaving only the peak corresponding to bulk zincblende InP. This possibly corresponds to the elimination of stacking faults. There is a strong correlation between the presence of stacking faults and the higher energy PL feature. However, without conclusive evidence and a satisfactory model for this hypothesis, we cannot establish a causal relationship. The possibility of other defects introduced at low growth temperatures cannot be ruled out as the source of the PL trend. Based on the PL characteristics, the optimal growth temperature is 520° C. At this growth temperature, there are no PL features remaining that do not appear in the single crystal reference.

### Experimental Section

Growth: The MOCVD system used was a Thomas Swann 3×2 CCS MOCVD. The chamber was a vertical cold-wall showerhead configuration. The susceptor held 3″ wafers and the rotation rate was fixed at 30 RPM. The precursors were Trimethylindium (TMIn) from Akzo Nobel and Tert-butylphosphine (TBP) from Dockweiler Chemicals. They were held at 20° C. and 10° C., respectively. TMIn was flowed at ˜1.2E−5 mol/min and TBP at ˜2.4E−3 mol/min, giving a [V]/[III] molar ratio of ˜200. Total flow of H₂ and precursors was 11.5 L/min. Growth temperatures ranged from 445° C. to 545° C. Growth times explored were 5-75 minutes, with 75 minutes used for the data in this discussion. The chamber pressure was fixed at 76 torr.

Characterization: SEM images were taken on a Zeiss Gemini Ultra-55. TEM was performed using a JEOL-3000F. The XRD was taken on a Bruker AXS D8 Discover GADDS XRD Diffractometer system. The PL excitation source was a 785 nm laser with ˜30 μm spot size, and the detector was a silicon CCD. Note that at this excitation, the penetration depth is ˜290 nm, so carriers are being generated mainly in the top quarter of the films. The reference InP sample was (100) orientation n-type doped with zinc to ˜10¹⁷/cm³. The excitation source for the backscatter Raman data was the 488 nm line from an Ar ion laser. The uncertainty of the Raman data is limited to ±0.3 cm⁻¹.

In summary, embodiments of the invention have demonstrated high optical quality poly InP grown on metal substrates. The resulting films are composed of micron-sized grains, and importantly show nearly identical PL and Raman spectral shape and position as those of a single-crystal reference. Additional embodiments of the invention will provide further characterization of the minority carrier lifetime, mobility, and diffusion length. Doping and the particulars of full device fabrication will be described as well. Embodiments of the invention describe a growth scheme that avoids using expensive single-crystal substrates and associated complex epitaxial structures, which have thus far hindered the market success of III-V solar cells. Metal foil substrates not only reduce cost at the material growth step, but also at downstream processing steps. For example, flexible foil substrates are a natural fit for roll-to-roll processing.^{[0042]} They are robust, light-weight, and act as excellent barriers to the environment. Poly-InP grown using the described technique shows great promise for high-efficiency, low-cost solar cells.

This invention has been described herein in considerable detail to provide those skilled in the art with information relevant to apply the novel principles and to construct and use such specialized components as are required. However, it is to be understood that the invention can be carried out by different equipment, materials and devices, and that various modifications, both as to the equipment and operating procedures, can be accomplished without departing from the scope of the invention itself.

### REFERENCES

[1] M. A. Green, K. Emery, Y. Hishikawa, W. Warta, Prog. Photovoltaics Res. Appl. 2011, 19, 84-92.
[2] C. J. Keavney, V. E. Haven, S. M. Vernon, in Conf. Rec. 21st IEEE Photovoltaic Spec. Conf. 1990, 1, 141-144.
[3] M. W. Wanlass, T. J. Coutts, J. S. Ward, K. A. Emery, in Conf. Rec. 22nd IEEE Photovoltaic Spec. Conf. 1991, 1, 159-165.
[4] J. Yoon, S. Jo, I. S. Chun, I. Jung, H.-S. Kim, M. Meitl, E. Menard, X. Li, J. J. Coleman, U. Paik and J. A. Rogers, Nature 2010, 465, 329-333.
[5] X. Y. Lee, A. K. Verma, C. Q. Wu, M. Goertemiller, E. Yablonovitch, J. Eldredge, D. Lillington, in Conf. Rec. 25th IEEE Photovoltaic Spec. Conf. 1996, 53-55.
[6] J. M. Zahler, K. Tanabe, C. Ladous, T. Pinnington, F. D. Newman, H. A. Atwater, Appl. Phys. Lett. 2007, 91, 012108.
[7] J. M. Zahler, A. Fontcuberta i Morral, Chang-Geun Ahn, H. A. Atwater, M. W. Wanlass, C. Chu, P. A. Iles, in Conf. Rec. 29th IEEE Photovoltaic Spec. Conf., 2002, 1039-1042.
[8] K. Lee, K.-T. Shiu, J. D. Zimmerman, C. K. Renshaw, S. R. Forrest, Appl. Phys. Lett. 2010, 97, 101107.
[9] T. Nakamura, T. Katoda, J. Appl. Phys. 1984, 55, 3064.
[10] Y. Rosenwaks, Y. Shapira, D. Huppert, Phys. Rev. B 1991, 44, 13097-13100.
[11] R. K. Ahrenkiel, D. J. Dunlavy, T. Hanak, J. Appl. Phys. 1988, 64, 1916.
[12] R. K. Ahrenkiel, D. J. Dunlavy, T. Hanak, Sol. Cells 1988, 24, 339-352.
[13] Y. Rosenwaks, Y. Shapira, D. Huppert, Phys. Rev. B 1992, 45, 9108-9119.
[14] S. Bothra, S. Tyagi, S. K. Ghandhi, J. M. Borrego, Solid-State Electron. 1991, 34, 47-50.
[15] D. D. Nolte, Solid-State Electron. 1990, 33, 295-298.
[16] L. Jastrzebski, J. Lagowski, H. C. Gatos, Appl. Phys. Lett. 1975, 27, 537-539.
[17] R. Venkatasubramanian, B. C. O'Quinn, J. S. Hills, P. R. Sharps, M. L. Timmons, J. A. Hutchby, H. Field, R. Ahrenkiel, B. Keyes, in Conf. Rec. 25th IEEE Photovoltaic Spec. Conf. 1996, 31-36.
[18] Y. C. M. Yeh, R. J. Stirn, Appl. Phys. Lett. 1978, 33, 401.
[19] T. Saitoh, S. Matsubara, S. Minagawa, Thin Solid Films 1978, 48, 339-344.
[20] T. Saitoh, S. Matsubara, S. Minagawa, Jpn. J. Appl. Phys. 1976, 15, 893-894.
[21] T. Saitoh, S. Matsubara, S. Minagawa, J. Electrochem. Soc. 1976, 123, 403-406
[22] T. Saitoh, S. Matsubara, J. Electrochem. Soc. 1977, 124, 1065-1069.
[23] T. Saitoh, S. Matsubara, S. Minagawa, Jpn. J. Appl. Phys. 1977, 16, 807-812.
[24] K. J. Bachmann, E. Buehler, J. L. Shay, S. Wagner, Appl. Phys. Lett. 1976, 29, 121.
[25] R. L. Woo, R. Xiao, Y. Kobayashi, L. Gao, N. Goel, M. K. Hudait, T. E. Mallouk, R. F. Hicks, Nano Lett. 2008, 8, 4664-4669.
[26] R. E. Algra, M. A. Verheijen, M. T. Borgstrom, L.-F. Feiner, G. Immink, W. J. P. van Enckevort, E. Vlieg, E. P. A. M. Bakkers, Nature 2008, 456, 369-372.
[27] H. Gottschalk, G. Patzer, H. Alexander, Phys. Status Solidi A 1978, 45, 207-217.
[28] P. I. Gaiduk, F. F. Komarov, V. S. Tishkov, W. Wesch, E. Wendler, Phys. Rev. B 2000, 61, 15785-15788.
[29] ICDD PDF-2. Entry 00-032-0452. 2003.
[30] G. F. Alfrey, P. H. Borcherds, J. Phys. C: Solid State Phys. 1972, 5, L275-L278.
[31] A. Mooradian, G. B. Wright, Solid State Commun. 1966, 4, 431-434.
[32] L. Artús, R. Cuscó, J. M. Martín, G. González-Díaz, Phys. Rev. B 1994, 50, 11552-11555.
[33] W. J. Turner, W. E. Reese, G. D. Pettit, Phys. Rev. 1964, 136, A1467-A1470.
[34] M. Bugajski, W. Lewandowski, J. Appl. Phys. 1985, 57, 521.
[35] G. Perna, V. Capozzi, V. Augelli, T. Ligonzo, L. Schiavulli, G. Bruno, M. Losurdo, P. Capezzuto, J. L. Staehli, M. Pallara, Semicond. Sci. Technol. 2001, 16, 377-385.

M. H. Lee, N. Lim, D. J. Ruebusch, A. Jamshidi, R. Kapadia, R. Lee, T. J. Seok, K. Takei, K. Y. Cho, Z. Fan, H. Jang, M. Wu, G. Cho, A. Javey, Nano Lett. 2011, 11, 3425-3430.

We claim:

1. A solar cell comprising;
a substrate;
a VIB metal thin film deposited on the substrate; and
a polycrystalline III-V semiconductor thin film deposited on the VIB metal thin film.

2. The solar cell of claim 1 wherein the substrate is a metal.

3. The solar cell of claim 2 wherein the metal substrate is a metal foil.

4. The solar cell of claim 2 wherein the metal substrate is Aluminum (Al).

5. The solar cell of claim 2 wherein the metal substrate is Molybenum (Mo).

6. The solar cell of claim 2 wherein the metal substrate is Tungsten (W).

7. The solar cell of claim 1 wherein the VIB metal thin film is Molybenum (Mo).

8. The solar cell of claim 1 wherein the VIB metal thin film is Tungsten (W).

9. The solar cell of claim 1 wherein the polycrystalline III-V semiconductor thin film is Indium Phosphide (InP).

10. The solar cell of claim 1 wherein the polycrystalline III-V semiconductor thin film is Gallium Arsenide (GaAs).

11. The solar cell of claim 1 wherein polycrystalline III-V semiconductor thin film is deposited utilizing Metal Organic Chemical Vapor Deposition (MOCVD).

12. A method of making a solar cell comprising;
providing a substrate;
depositing a VIB metal thin film deposited on the substrate; and
depositing a polycrystalline III-V semiconductor thin film on the VIB metal thin film.

13. The method of claim 12 wherein the substrate is a metal.

14. The method of claim 13 wherein the metal substrate is a metal foil.

15. The method claim 13 wherein the metal substrate is Aluminum (Al).

16. The method of claim 13 wherein the metal substrate is Molybenum (Mo).

17. The method of claim 13 wherein the metal substrate is Tungsten (W).

18. The method of claim 12 wherein the VIB metal thin film is Molybenum (Mo).

19. The method of claim 12 wherein the VIB metal thin film is Tungsten (W).

20. The method of claim 12 wherein the polycrystalline III-V semiconductor thin film is Indium Phosphide (InP).

21. The method of claim 12 wherein the polycrystalline III-V semiconductor thin film is Gallium Arsenide (GaAs).

22. The method of claim 12 wherein polycrystalline III-V semiconductor thin film is deposited utilizing Metal Organic Chemical Vapor Deposition (MOCVD).
